(19) United States
(12) Patent Application Publication
(10) Pub. No.: US 2009/0308646 A1
(43) Pub. Date: Dec. 17, 2009

(54) CONDUCTOR PATTERN FORMING INK, CONDUCTOR PATTERN, AND WIRING SUBSTRATE

(75) Inventor: Naoyuki TOYODA, Suwa (JP)

Correspondence Address: HARNESS, DICKEY & PIERCE, P.L.C., P.O. BOX 828, BLOOMFIELD HILLS, MI, 48303, US

(73) Assignee: SEIKO EPSON CORPORATION, Tokyo (JP)

(21) Appl. No.: 12/430,358

(22) Filed: Apr. 27, 2009

(30) Foreign Application Priority Data
Jun. 12, 2008 (JP) 2008-154709
Jun. 12, 2008 (JP) 2008-154710

(51) Int. Cl. H05K 1/09; C09D 11/00

(52) U.S. Cl. 174/257; 106/31.92

(57) ABSTRACT

A conductor pattern forming ink for forming a conductor pattern on a substrate by a droplet discharge method includes: metal particles; an aqueous dispersion medium in which the metal particles are dispersed; and at least one of a compound expressed by Formula (I) below and alkanolamine.

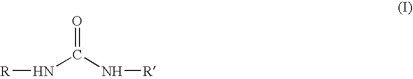

Here, R and R′ are respectively one of H and an alkyl group.

### BACKGROUND

1. Technical Field

The present invention relates to a conductor pattern forming ink, a conductor pattern, and a wiring substrate.

2. Related Art

To provide wiring used for electronic circuits, integrated circuits, or the like, photolithography is used, for example. Photolithography is such a method that a thin film wiring pattern composed of a conductor pattern is formed by coating a photosensitive material called a resist on a substrate on which a conductive film is coated in advance, exposing and developing a circuit pattern, and then etching the conductive film corresponding to a resist pattern. However, photolithography needs large-scale equipment such as a vacuum apparatus and a complicated process. In addition, efficiency in the use of materials is about several percent, thus wasting almost all the materials and requiring high manufacturing costs.

On the other hand, JP-A-2007-84387, for example, discloses such a method that a wiring pattern (wiring) is formed on a substrate by using a droplet discharge method, that is, an inkjet method in which a liquid material is discharged from a liquid discharge head as a droplet. In the method, a conductor pattern forming ink, in which conductive fine particles are dispersed, is directly pattern-applied on a substrate, then a solvent is removed, and sintering is conducted so as to convert the ink into the conductor pattern. This method requires no photolithography, thus substantially simplifying the process and reducing used amount of raw materials.

In this regard, a related art conductor pattern forming ink has a problem in that conductive fine particles are separated out from the ink due to volatilization of a dispersion medium of the ink around a droplet discharge portion of a droplet discharge head (ink-jet head) during a discharge waiting time and a long time continuing discharge. The conductive fine particles separated out around the droplet discharge portion cause change of paths of discharged droplets, that is, a flight curve occurs, resulting in problems in that the droplets are hardly landed on targeted parts and the discharge amount of the droplet is unstable.

### SUMMARY

An advantage of the present invention is to provide a conductor pattern forming ink that can be stably discharged from a droplet discharge head, a conductor pattern which is reliable, and a wiring substrate which is provided with such conductor pattern so as to be highly reliable.

The advantage described above is achieved by aspects of the present invention described below.

According to a first aspect of the invention, a conductor pattern forming ink for forming a conductor pattern on a substrate by a droplet discharge method, includes: metal particles; an aqueous dispersion medium in which the metal particles are dispersed; and at least one of a compound expressed by Formula (I) below and alkanolamine.

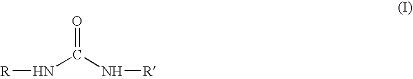

Here, R and R′ are respectively one of H and an alkyl group.

Accordingly, the conductor pattern forming ink that can be stably discharged from a droplet discharge head can be provided.

In the conductor pattern forming ink of the aspect, it is preferable that a content of one of the compound expressed by Formula (I) and alkanolamine be 5 wt % to 25 wt %.

Accordingly, the conductor pattern forming ink can be more efficiently prevented from undesirably drying. As a result, the ink obtains highly excellent discharge stability.

In the conductor pattern forming ink of the aspect, it is preferable that alkanolamine be tertiary amine.

Further, it is preferable that tertiary amine is triethanolamine.

Accordingly, a moisture-retaining property of the conductor pattern forming ink can be further improved and the aqueous dispersion medium of the ink can be more efficiently prevented from undesirably volatilizing.

It is preferable that the conductor pattern forming ink further includes sugar alcohol.

Accordingly, the aqueous dispersion medium can be more securely prevented from volatilizing around a discharge part of an ink-jet device, being able to prevent the ink from increasing its viscosity and drying. As a result, the discharge stability of the ink is further improved.

In the conductor pattern forming ink, it is preferable that a content of sugar alcohol be 3 wt % to 20 wt %.

This can more securely prevent the volatilization of the aqueous dispersion medium of the conductor pattern forming ink, whereby the conductor pattern forming ink exhibits excellent discharge stability for a longer period of time.

In the conductor pattern forming ink, it is preferable that the substrate be formed by degreasing and sintering a ceramic formed body made of a material containing ceramic particles and a binder so as to have a sheet like shape, and the conductor pattern forming ink be applied to the ceramic formed body by the droplet discharge method.

The conductor pattern forming ink of the aspect can be favorably used for forming a conductor pattern on such a ceramic formed body.

It is preferable that the conductor pattern forming ink be a colloidal liquid obtained by dispersing metal colloidal particles composed of the metal particles and a dispersant covering surfaces of the metal particles in the aqueous dispersion medium.

Accordingly, agglomeration of the metal particles in the conductor pattern forming ink is prevented, so that discharge stability is improved and a finer conductor pattern can be formed.

In the conductor pattern forming ink of the aspect, it is preferable that the dispersant include one of mercapto acid and salt of mercapto acid having in total two or more of at least one COOH group and at least one SH group.

Accordingly, agglomeration of the metal particles in the ink is prevented, so that discharge stability is improved and a finer conductor pattern can be formed.

In the conductor pattern forming ink of the aspect, it is preferable that the colloidal liquid have a pH of 6 to 12.

Accordingly, agglomeration of the metal particles in the ink is prevented, so that discharge stability is improved and a finer conductor pattern can be formed.

According to a second aspect of the invention, a conductive pattern is formed from the conductor pattern forming ink of the first aspect.

Accordingly, the conductor pattern having high reliability can be provided.

According to a third aspect, a wiring substrate is provided with the conductor pattern of the second aspect.

Accordingly, the wiring substrate having high reliability can be provided.

### BRIEF DESCRIPTION OF THE DRAWINGS

The invention will be described with reference to the accompanying drawings, wherein like numbers reference like elements.

FIG. 1 is a longitudinal sectional view illustrating a wiring substrate (ceramic circuit substrate) of the invention.

FIG. 2 is an explanatory diagram showing a schematic process of a method for manufacturing a wiring substrate (ceramic circuit substrate) shown in FIG. 1.

FIGS. 3A and 3B are explanatory diagrams showing manufacturing steps of the wiring substrate (ceramic circuit substrate) shown in FIG. 1.

FIG. 4 is a perspective view showing a schematic configuration of an ink-jet device.

FIG. 5 is a diagram for explaining a schematic configuration of an ink-jet head.

### DESCRIPTION OF EXEMPLARY EMBODIMENTS

Preferable embodiments of the invention will be described below.

### First Embodiment

Conductor Pattern Forming Ink

A conductor pattern forming ink according to a first embodiment of the invention is used for forming a conductor pattern on a substrate, especially used for forming a conductor pattern by a droplet discharge method.

Any substrate may be used as a substrate on which a conductor pattern is formed. However, in the embodiment, a ceramic substrate is employed as the substrate. Further, the first embodiment will be described by exemplifying a case where the conductor pattern forming ink is applied to a ceramic formed body (a ceramic green sheet) made of ceramic and a material containing a binder and having a sheet-like shape. Here, the ceramic formed body and the ink applied to the ceramic formed body undergo a sintering step as described later so as to be a ceramic substrate and a conductor pattern respectively.

The conductor pattern forming ink will now be descried. In the embodiment, a case using a dispersion liquid in which silver particles are dispersed will be described as a typical one of dispersion liquids obtained by dispersing metal particles in an aqueous dispersion medium.

The conductor pattern forming ink (hereinafter, referred to as merely an ink, as well) contains an aqueous dispersion medium, silver particles (metal particles) dispersed in the aqueous dispersion medium, and at least one of a compound expressed by Formula (I) below and alkanolamine.

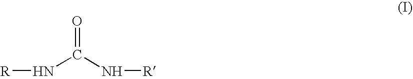

### (Here, R and R′ are Respectively H or an Alkyl Group.)

Constituents of the conductor pattern forming ink will be descried below.

Aqueous Dispersion Medium

The aqueous dispersion medium will be first described.

In the embodiment, the “aqueous dispersion medium” is water and/or a liquid having an excellent compatibility with respect to water (a liquid with a solubility of 30 grams or more per 100 grams of water at 25 degrees Celsius). Thus the aqueous dispersion medium is composed of water and/or the liquid having the excellent compatibility with respect to water, but the aqueous dispersion medium mainly composed of water is preferably used. Especially, the aqueous dispersion medium preferably contains water at a content rate of 70 wt % or more, more preferably at a content rate of 90 wt % or more.

Examples of the aqueous dispersion medium include: water; an alcohol solvent such as methanol, ethanol, butanol, propanol, and isopropanol; an ether solvent such as 1,4-dioxane, and tetrahydrofuran (THF); an aromatic heterocyclic compound solvent such as pyridine, pyrazine, and pyrrole; an amide solvent such as N,N-dimethylformamide (DMF), and N,N-dimethylacetamide (DMA); a nitrile solvent such as acetonitrile; and an aldehyde solvent such as acetoaldehyde. These may be used singly or in combination of two or more.

The content of the aqueous dispersion medium in the conductor pattern forming ink is preferably in the range from 25 wt % to 60 wt %, more preferably from 30 wt % to 50 wt %. Accordingly, the ink has a suitable viscosity and viscosity variation caused by volatilization of the dispersion medium is lessened.

Silver Particle

The silver particles (metal particles) will now be described.

The silver particles are a main component of the conductor pattern to be formed and provide conductivity to the conductor pattern.

The silver particles are dispersed in the ink.

The average particle diameter of the silver particles is preferably in the range from 1 nm to 100 nm, more preferably from 10 nm to 30 nm. Accordingly, discharge stability of the ink can be improved and therefore a fine conductor pattern can be easily formed. Here, in the embodiment, the “average particle diameter” means an average particle diameter on volumetric basis if not otherwise specified.

Further, an average particle distance between the silver particles is preferably in the range from 1.7 nm to 380 nm, more preferably in the range from 1.75 nm to 300 nm. Accordingly, the conductor pattern forming ink has more suitable viscosity and has highly excellent discharge stability.

The content of the silver particles (silver particles (metal particles) having a surface onto which no dispersant adsorbs) contained in the ink is preferably in the range from 0.5 wt % to 60 wt %, more preferably from 10 wt % to 45 wt %. Accordingly, disconnections of the conductor pattern can be more effectively prevented, being able to provide the conductor pattern having higher reliability.

The silver particles (metal particles) are preferably dispersed in the aqueous dispersion medium as silver colloidal particles (metal colloidal particles) covered by the dispersant on their surfaces. Accordingly, the dispersibility of the silver particles with respect to the aqueous dispersion medium is improved, especially improving the discharge stability of the ink.

The dispersant is not particularly limited, but preferably includes hydroxyl acid or its salt in which three or more of COOH groups and OH groups in total are included, and the number of COOH groups is same as that of OH groups or more than that. The dispersant adsorbs onto the surfaces of the silver particles so as to form colloidal particles, and evenly disperses the silver colloidal particles in the aqueous solution by electrical repulsion of COOH groups present in the dispersion medium so as to stabilize a colloidal liquid. Thus the silver colloidal particles are stably present in the ink, making it easier to form a fine conductor pattern. In addition, the silver particles are evenly distributed in the pattern (precursor) formed from the ink, so that cracks, disconnections, and the like do not easily occur. On the other hand, if the total number of COOH groups and OH groups is less than three, or the number of COOH groups is less than that of OH groups, sufficient dispersibility of the silver colloidal particles may not be obtained.

Examples of such dispersant include: citric acid, malic acid, trisodium citrate, tripotassium citrate, trilithium citrate, ammonium citrate tribasic, disodium malate, tannic acid, gallotannic acid, and gallnut tannin. These may be used singly or in combination of two or more.

Alternatively, mercapto acid or its salt having two or more of COOH groups and SH groups in total may be included in the dispersant. The dispersant forms colloidal particles by the adsorption of mercapto groups onto the surfaces of the silver particles, and evenly disperses the colloidal particles in the aqueous solution by electrical repulsion of COOH groups present in the dispersion medium so as to stabilize a colloidal liquid. Thus the silver colloidal particles are stably present in the ink, making it easier to form a fine conductor pattern. In addition, the silver particles are evenly distributed in the pattern (precursor) formed from the ink, so that cracks, disconnections, and the like do not easily occur. On the other hand, if the total number of COOH groups and SH groups in the dispersant is less than two, that is, only either one of a COOH group and a SH group is present, sufficient dispersibility of the silver colloidal particles may not be obtained.

Examples of such dispersant includes: mercaptoacetic acid, mercaptopropionic acid, thiodipropionic acid, mercaptosuccinic acid, thioacetic acid, sodium mercaptoacetate, mercaptopropionic acid sodium, thiodipropionic acid sodium, mercaptosuccinic acid disodium, potassium mercaptoacetate, mercaptopropionic acid potassium, thiodipropionic acid potassium, and mercaptosuccinic acid dipotassium. These may be used singly or in combination of two or more.

The content of the silver colloidal particles in the ink is preferably in the range from about 1 wt % to about 60 wt %, more preferably from about 10 wt % to about 50 wt %. If the content of the silver colloidal particles is less than the lower limit of the range above, the ink needs to be applied more than once because of a small content of silver in a case where a relatively thick film is formed in forming the conductor pattern. On the other hand, if the content of the silver colloidal particles exceeds the upper limit of the range above, the dispersibility is decreased because of a large content of silver. In this case, the frequency of stirring needs to be increased so as to prevent the decrease of the dispersibility.

The loss on heating, up to 500 degrees Celsius in the thermogravimetric analysis, of the silver colloidal particles is preferably from about 1 wt % to about 25 wt %. If colloidal particles (solid content) are heated up to 500 degrees Celsius, the dispersant covering the surfaces, a reducing agent (residual reducing agent) described later, and the like are oxidized and decomposed so as to be mostly gasified and disappear. An amount of the residual reducing agent is seemed to be small, so that it may be considered that the loss on heating up to 500 degrees Celsius nearly corresponds to the amount of the dispersant adsorbing on the silver colloidal particles. If the loss on heating is less than 1 wt %, the dispersibility of the silver particles is decreased due to a small amount of the dispersant with respect to the silver particles. On the other hand, if the loss on heating exceeds 25 wt %, specific resistance of the conductor pattern is increased due to a large amount of residual dispersant with respect to the silver particles. Here, the specific resistance can be improved to some extent in such manner that the conductor pattern is heated and sintered after it is formed so as to decompose and dissipate an organic component thereof. Therefore, larger improving effect can be obtained in a case of a ceramic substrate, for example, that is sintered in higher temperature.

Forming of the silver colloidal particles will be described later.

Compound Expressed by Formula (I)

The conductor pattern forming ink of the embodiment contains the compound expressed by Formula (I).

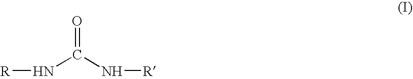

Here, R and R′ are respectively H or an alkyl group.

The compound expressed by Formula (I) has a high hydrogen-bonding property. Thus, the compound has high hydrophilic property and therefore can maintain adequate moisture so as to be able to prevent undesired volatilization of the aqueous dispersion medium of the conductor pattern forming ink. As a result, the aqueous dispersion medium can be prevented from volatilizing around a discharge part of an inkjet device, being able to prevent the ink from increasing its viscosity and drying. Consequently, the discharge stability of droplets of the ink is highly improved. That is, variation in weight of droplets of the ink is small, resulting in little clogging and little flying failure. In particular, even in a case where the ink-jet device supplied with the conductor pattern forming ink is left for a long period of time (e.g. 5 days) without being operated so as to be in a waiting state, the conductor pattern forming ink according to the invention is accurately discharged on target positions in a uniform amount.

Further, the compound above burns with relative ease, thereby being more easily removed (oxidized and decomposed) from the conductor pattern in forming the conductor pattern.

Further, the concentration of the compound above increases as the aqueous dispersion medium volatilizes in drying (removing the dispersion medium) the pattern formed from the conductor pattern forming ink. Accordingly, the viscosity of the precursor of the conductor pattern is increased, securely preventing the ink constituting the precursor from flowing to an undesired region. As a result, the conductor pattern can be formed in a desired shape with high degree of accuracy.

Further, only a little amount of the aqueous dispersion medium volatilizes from the conductor pattern forming ink, so that the conductor pattern forming ink exhibits little variation in properties such as viscosity for a long period of time, thus achieving an excellent stability.

Further, in a case where the metal particles (silver particles) are colloidal particles that are covered by the dispersant on their surfaces, the compound mentioned above bonds with the dispersant on the surfaces due to hydrogen bonding. Thus, the compound above has an advantageous effect of improving the dispersion stability of the metal particles. Accordingly, the conductor pattern forming ink obtains excellent discharge stability and excellent storing stability.

As described above, R and R′ in the compound expressed by Formula (I) in the invention are a hydrogen group or an alkyl group. However, both of R and R′ are preferably hydrogen groups. That is, R and R′ are preferably urea. Accordingly, the moisture-retaining property can be highly improved and highly excellent discharge stability can be obtained. Further, in a case where the metal particles exist as the colloidal particles as described above, the particles exhibits especially excellent dispersion stability.

A content of the compound expressed by Formula (I) in the ink is preferably in the range from 5 wt % to 25 wt %, more preferably in the range from 8 wt % to 20 wt %, and furthermore preferably in the range from 10 wt % to 18 wt %. Accordingly, the conductor pattern forming ink can be more efficiently prevented from undesirably drying. As a result, the ink obtains especially excellent discharge stability.

Alkanolamine

The conductor pattern forming ink may contain alkanolamine. Alkanolamine has a high moisture-retaining property as is the case with the compound expressed by Formula (I). Therefore, the conductor pattern forming ink can be more securely prevented from undesirably drying, thus improving the discharge stability of the conductor pattern forming ink. In the case where the ink contains alkanolamine, the amine group of the compound expressed by Formula (I) is activated so as to improve the hydrogen bonding property of the compound expressed by Formula (I). As a result, the moisture-retaining property of the conductor pattern forming ink can be further improved and the aqueous dispersion medium of the ink can be more effectively prevented from undesirably volatilizing.

In particular, even in a case where the ink-jet device supplied with the conductor pattern forming ink is left for a long period of time (e.g. 5 days) without being operated so as to be in a waiting state, the conductor pattern forming ink according to the invention is accurately discharged on target positions in a uniform amount.

Further, in a case where the metal particles are the colloidal particles as described above, a functional group of the dispersant covering the surfaces of the colloidal particles can be activated, being able to further improve the dispersion stability of the metal particles.

Further, alkanolamine burns with relative ease, thereby being more easily removed (oxidized and decomposed) from the conductor pattern in forming the conductor pattern.

Further, only a little amount of the aqueous dispersion medium volatilizes from the conductor pattern forming ink, so that the conductor pattern forming ink exhibits little variation in properties such as viscosity for a long period of time and thus obtains an excellent preserving property.

Examples of alkanolamine includes: monoethanolamine, diethanolamine, triethanolamine, monopropanolamine, dipropanolamine, and tripropanolamine.

Alkanolamine is preferably tertiary amine. Tertiary amine has especially high moisture-retaining property among alkanolamines, notably exhibiting the advantageous effect mentioned above.

Among the tertiary amine, triethanolamine is preferably adopted due to ease in handling and high moisture-retaining property thereof.

The content of alkanolamine in the conductor pattern forming ink is preferably in the range from 1 wt % to 10 wt %, more preferably from 3 wt % to 7 wt %. Accordingly, the discharge stability of the conductor pattern forming ink can be more efficiently improved.

Other Component

The conductor pattern forming ink may contain organic binder. The organic binder prevents agglomeration of the silver particles in the pattern formed from the conductor pattern forming ink. That is, the organic binder exists between the silver particles so as to prevent occurrence of cracks, which is caused by the agglomeration of the silver particles, on a part of the pattern. Further, the organic binder can be decomposed and removed in the sintering and the silver particles in the pattern bond with each other so as to form a conductor pattern.

Thus, the organic binder can prevent the occurrence of cracks on the conductor pattern to be formed. However, the organic binder commonly agglomerates in the ink with ease. However, the compound expressed by Formula (I) contained in the ink bonds with the organic binder by the hydrogen bonding so as to improve the dispersion stability of the organic binder in the aqueous dispersion medium. Thus the organic binder can be prevented from undesirably agglomerating.

The organic binder is not limited, and examples of the organic binder include: polyethylene glycol such as polyethylene glycol #200 (weight-average molecular weight of 200), polyethylene glycol #300 (weight-average molecular weight of 300), polyethylene glycol #400 (weight-average molecular weight of 400), polyethylene glycol #600 (weight-average molecular weight of 600), polyethylene glycol #1000 (weight-average molecular weight of 1000), polyethylene glycol #1500 (weight-average molecular weight of 1600), polyethylene glycol #1540 (weight-average molecular weight of 1540), and polyethylene glycol #2000 (weight-average molecular weight of 2000); polyvinyl alcohol such as polyvinyl alcohol #200 (weight-average molecular weight of 200), polyvinyl alcohol #300 (weight-average molecular weight of 300), polyvinyl alcohol #400 (weight-average molecular weight of 400), polyvinyl alcohol #600 (weight-average molecular weight of 600), polyvinyl alcohol #1000 (weight-average molecular weight of 1000), polyvinyl alcohol #1500 (weight-average molecular weight of 1500), polyvinyl alcohol #1540 (weight-average molecular weight of 1540), and polyvinyl alcohol #2000 (weight-average molecular weight of 2000); and a polyglycerol compound having a polyglycerol skeleton such as polyglycerol and polyglycerol ester. These may be used singly or in combination of two or more. Examples of polyglycerol ester include: polyglycerol monostearate, polyglycerol tristearate, polyglycerol tetrastearate, polyglycerol monooleate, polyglycerol pentaoleate, polyglycerol monolaurate, polyglycerol monocaprylate, polyglycerol polycinoleate, polyglycerol sesquistearate, polyglycerol decaoleate, and polyglycerol sesquioleate.

Among these, in a case where the polyglycerol compound is used as the organic binder, the following advantageous effects are obtained.

The polyglycerol compound can especially suitably prevent the occurrence of cracks in a pattern formed from the conductor pattern forming ink when the pattern (precursor of the conductor pattern described in detail later) is dried (the dispersion medium is removed). This can be considered as follows. If the conductor pattern forming ink contains the polyglycerol compound, polymer chains are present between the silver particles (metal particles), and thus the polyglycerol compound can maintain an appropriate distance between the silver particles. Further, since the boiling point of the polyglycerol compound is relatively high, the compound is not removed in removing the aqueous dispersion medium, and adsorbs onto the circumference of the silver particles. Accordingly, a state that the polyglycerol compound wraps around the silver particles is kept for long periods of time in removing the aqueous dispersion medium, so that rapid volume constriction caused by the volatilization of the aqueous dispersion medium can be avoided and the grain growth (agglomeration) of silver can be prevented, suppressing the occurrence of cracks in the pattern.

Further, the polyglycerol compound can more securely prevent occurrence of disconnections in the sintering in a process of forming the conductor pattern. This can be considered as follows. The polyglycerol compound has a relatively high boiling point or a relatively high decomposition temperature. Therefore, in the process of forming the conductor pattern from the conductor pattern forming ink, the polyglycerol compound can be left in the pattern up to relatively high temperature without evaporating or thermally (oxidatively) decomposing the compound after the aqueous dispersion medium is evaporated. Therefore, the polyglycerol compound exists at the circumference of the silver particles until the polyglycerol compound is evaporated or thermally (oxidatively) decomposed, so as to suppress approach and agglomeration of the silver particles. After the polyglycerol compound is decomposed, the silver particles can be bonded to each other more evenly. Since the polymer chains (polyglycerol compound) exist between the silver particles (metal particles) in the sintering, the polyglycerol compound can maintain a distance between the silver particles. Further, the polyglycerol compound has an appropriate fluidity. Therefore, if the ink contains the polyglycerol compound, the precursor of the conductor pattern favorably follows expansion and constriction caused by the temperature change of the ceramic formed body.

Thus the occurrence of disconnections in the conductor pattern that is formed can be more securely prevented.

Further, the ink containing such polyglycerol compound obtains suitable viscosity, more effectively improving the discharge stability of the ink from the ink-jet head. In addition, the film-forming property also can be improved.

As the polyglycerol compound, polyglycerol is preferably used among the above-mentioned substances. Polyglycerol especially favorably follows expansion and constriction caused by the temperature change of the ceramic formed body and is more securely removed from the conductor pattern after the sintering of the ceramic formed body. As a result, an electric property of the conductor pattern can be enhanced. Further, polyglycerol has high solubility with respect to the aqueous dispersion medium so as to be preferably used.

The organic binder preferably has a weight-average molecular weight in the range from 300 to 3000, more preferably from 400 to 1000, and further more preferably from 400 to 600. Consequently, the occurrence of cracks can be more securely prevented when the pattern that is formed from the conductor pattern forming ink is dried. In addition, in a case where the ink contains sugar alcohol, the organic binder shows high affinity with sugar alcohol. Therefore, in the sintering, the pattern formed from the ink can maintain high fluidity for long periods of time so as to especially favorably follow expansion and constriction, caused by the temperature change, of the ceramic formed body. If the weight-average molecular weight of the organic binder is lower than the lower limit of the range above, the organic binder tends to be easily decomposed when the aqueous dispersion medium is removed depending on the composition of the organic binder, decreasing the effect preventing the occurrence of cracks. If the weight-average molecular weight of the polyglycerol compound exceeds the upper limit of the range above, the solubility and the dispersibility in the ink may be decreased depending on the composition of the organic binder due to a removing volume effect and the like.

A content of the organic binder in the ink is preferably in the range from 1 wt % to 30 wt %, more preferably in the range from 5 wt % to 20 wt %. Accordingly, the discharge stability of the ink is highly improved and the occurrence of cracks and disconnections can be more efficiently prevented. If the content of the organic binder is lower than the lower limit of the above range, the effect of preventing the occurrence of cracks may be decreased. If the content of the organic binder exceeds the upper limit of the above range, it may become hard to sufficiently decrease the viscosity of the ink depending on the composition of the organic binder.

The conductor pattern forming ink may contain sugar alcohol as well as the above-mentioned components.

Sugar alcohol is obtained by reducing an aldehyde group and a ketone group of sugar.

Sugar alcohol contributes to prevention of volatilization of the aqueous dispersion medium of the conductor pattern forming ink as is the case with the compound expressed by Formula (I) described above. In a case where the conductor pattern forming ink contains sugar alcohol, the aqueous dispersion medium can be more securely prevented from volatilizing around the discharge part of the inkjet device due to a synergetic effect with the moisture-retaining property of the compound expressed by Formula (I). Thus the ink is prevented from increasing its viscosity and drying. Consequently, the discharge stability of the ink is further improved.

Further, sugar alcohol is easily decomposed and removed when the atmosphere reaches a decomposition temperature of sugar alcohol, due to its large number of oxygen per molecular weight. Therefore, in forming the conductor pattern, sugar alcohol can be securely removed (oxidized and decomposed) from the conductor pattern by setting the temperature of the conductor pattern to be higher than the decomposition temperature of sugar alcohol.

Examples of sugar alcohol include: threitol, erythritol, pentaerythritol, dipentaerythritol, tripentaerythritol, arabitol, ribitol, xylitol, sorbitol, mannitol, threitol, gulitol, talitol, galactitol, allitol, altritol, dulcitol, iditol, glycerin (glycerol), inositol, maltitol, isomaltitol, lactitol, and turanitol. These may be used singly or in combination of two or more.

A content of sugar alcohol described above in the conductor pattern forming ink is preferably in the range from 3 wt % to 20 wt %, more preferably in the range from 5 wt % to 15 wt %. This can more securely prevent the volatilization of the aqueous dispersion medium of the conductor pattern forming ink, whereby the conductor pattern forming ink exhibits excellent discharge stability for a longer period of time.

Further, the conductor pattern forming ink may contain an acetylene glycol based compound as well as the above-mentioned components. The acetylene glycol based compound adjusts a contact angle between the conductor pattern forming ink and the ceramic formed body so as to set the angle to be in a predetermined range. In addition, a small additive amount of the acetylene glycol based compound can adjust the contact angle between the conductor pattern forming ink and the ceramic formed body so as to set the angle to be in the predetermined range. The contact angle between the conductor pattern forming ink and the ceramic formed body is thus adjusted to be in the predetermined range, being able to form a finer conductor pattern. Further, even if bubbles are mixed in discharged droplets, the bubbles can be removed promptly. As a result, the occurrence of cracks and disconnections on the conductor pattern to be formed can be more efficiently prevented.

The compound described above, in particular, adjusts the contact angle between the conductor pattern forming ink and the ceramic formed body to set the angle to be in the range from 40 degrees to 80 degrees (more preferably, 50 degrees to 80 degrees). If the contact angle is too small, it sometimes becomes hard to form a conductor pattern having a fine line width. On the other hand, if the contact angle is too large, it sometimes becomes hard to form a conductor pattern having an even line width depending on discharging conditions. Further, it sometimes happens that a contact area between a landed droplet and the ceramic formed body is too small, and therefore the landed droplet moves out of its landing position.

Examples of the acetylene glycol based compound include: Surfynol 104 series (104E, 104H, 104PG-50, 104PA, and the like), Surfynol 400 series (420, 465, 485, and the like), and Olfine series (EXP4036, EXP4001, E1010, and the like) (“Surfynol” is a product name of Air Products and Chemicals, Inc. and “Olfine” is a product name of Nissin Chemical Industry Co., Ltd). These may be used singly or in combination of two or more.

The ink preferably contains two or more kinds of acetylene glycol based compounds having different hydrophile-lipophile balance (HLB) values from each other. Accordingly, the contact angle between the conductor pattern forming ink and the ceramic formed body can be more easily adjusted to be in the predetermined range. Especially, among two or more of acetylene glycol based compounds contained in the ink, the difference between an HLB value of the acetylene glycol based compound having the highest HLB value and an HLB value of the compound having the lowest HLB value is preferably in the range from 4 to 12, more preferably from 5 to 10. Accordingly, with a smaller additive amount of the acetylene glycol based compound, the contact angle between the conductor pattern forming ink and the ceramic formed body can be adjusted so as to be in the predetermined range.

In a case where the ink containing two or more kinds of acetylene glycol based compounds is used, the HLB value of the acetylene glycol based compound having the highest HLB value is preferably in the range from 8 to 16, more preferably from 9 to 14.

Further, in a case where the ink containing two or more kinds of acetylene glycol based compounds is used, the HLB value of the acetylene glycol based compound having the lowest HLB value is preferably in the range from 2 to 7, more preferably from 3 to 5.

The content of the acetylene glycol based compound in the ink is preferably in the range from 0.001 wt % to 1 wt %, more preferably 0.01 wt % to 0.5 wt %. Accordingly, the contact angle between the conductor pattern forming ink and the ceramic formed body can be more effectively adjusted to be in the predetermined range.

Furthermore, the conductor pattern forming ink may contain 1,3-propanediol as well as the above-mentioned components. Accordingly, the volatilization of the aqueous dispersion medium around the discharge portion of the ink-jet head can be more effectively suppressed. Therefore, the ink obtains a more suitable viscosity, further improving the discharge stability.

In a case where the ink contents 1,3-propanediol, the content of it is preferably 0.5 wt % to 20 wt %, more preferably 2 wt % to 10 wt %. Accordingly, the discharge stability of the ink can be more effectively improved.

Here, it should be noted that components of the conductor pattern forming ink are not limited to the above but the ink may contain other components.

The conductor pattern forming ink may contain, for example, multiple alcohol such as ethylene glycol, 1,3-butylene glycol, and propylene glycol. Further, the conductor pattern forming ink may contain thiourea as well as urea described above.

### Second Embodiment

Method for Producing Conductor Pattern Forming Ink

An example of a method for producing a conductor pattern forming ink such as the ink described above will now be described as a second embodiment of the invention. In the second embodiment, the conductor pattern forming ink is a colloidal liquid obtained by dispersing silver colloidal particles in an aqueous dispersion medium.

In producing a conductor pattern forming ink, an aqueous solution in which a dispersant and a reducing agent are dissolved is first prepared.

The dispersant is preferably blended in such amount that a molar ratio between silver of silver salt such as silver nitrate which is a starting substance and the dispersant is set to be about 1:1 to about 1:100. If the molar ratio of the dispersant with respect to silver salt is increased, a particle diameter of the silver particles is decreased. Therefore, contact points between the particles in the formed conductor pattern are increased, being able to obtain a film having a low volume-resistance value.

The reducing agent reduces Ag⁺ ions in silver salt such as silver nitrate (Ag⁺NO³⁻) which is a starting substance so as to produce silver particles.

The reducing agent is not especially limited. Examples of the reducing agent includes: amins such as hydrazine, dimethylaminoethanol, methyldiethanolamine, and triethanolamine; hydrogen compounds such as sodium borohydride, hydrogen gas, and hydrogen iodide; oxides such as carbon monoxide, sulfurous acid, and hypophosphorous acid; low-valent metal salts such as Fe(II) compound, and Sn(II) compound; sugars such as D-glucose; organic compounds such as formaldehyde; hydroxy acids, which are described as the dispersant above, such as citric acid, and malic acid; hydroxyacid salts such as trisodium citrate, tripotassium citrate, trilithium citrate, ammonium citrate tribasic, and disodium malate; and tannic acids. Among these, tannic acids and hydroxyl acids function not only as the reducing agent but also the dispersant so as to be preferably used. Preferable examples of the dispersant for forming a stable bond on surfaces of metals include: mercapto acids such as mercaptoacetic acid, mercaptopropionic acid, thiodipropionic acid, mercaptosuccinic acid, and thioacetic acid; and mercaptoacid salts such as sodium mercaptoacetate, mercaptopropionic acid sodium, thiodipropionic acid sodium, mercaptosuccinic acid sodium, potassium mercaptoacetate, mercaptopropionic acid potassium, thiodipropionic acid potassium, and mercaptosuccinic acid potassium. These dispersants and reducing agents may be used singly or in combination of two or more. When any of these compounds is used, the reduction reaction may be promoted with light or heat.

The reducing agent should be blended in such amount that the agent can completely reduce silver salt which is the starting substance. However, it should be blended at a minimum necessary amount, because if the reducing agent is blended excessively, it remains in the silver colloidal liquid as an impurity, causing deterioration of the conductivity after film forming. Specifically, the reducing agent is blended such that a molar ratio between silver salt and the reducing agent is about 1:1 to about 1:3.

In the second embodiment, after the aqueous solution is prepared by dissolving the dispersant and the reducing agent, a pH of the aqueous solution is preferably adjusted to be 6 to 12.

This is because of the following reasons. For example, in a case where trisodium citrate serving as the dispersant and ferrous sulfate serving as the reducing agent are blended, a pH is about 4 to about 5, that is, lower than 6 which is described above, though it varies depending on the whole concentration. In this case, hydrogen ions shift the equilibrium of the reaction expressed by the following Formula (1) to the right side of the formula, increasing the amount of COOH. Therefore, the electrical repulsion of the surfaces of the silver particles, which are obtained by delivering a silver salt solution by drops into the aqueous solution after this mixing, is reduced, reducing the dispersibility of the silver particles (colloidal particles).

—COO⁻+H⁺→COOH (1)

Because of this, after the aqueous solution is prepared by dissolving the dispersant and the reducing agent, an alkaline compound is added to the aqueous solution so as to decrease the concentration of hydrogen ions.

The alkaline compound to be added is not especially limited, but sodium hydroxide, potassium hydroxide, lithium hydroxide, ammonia water, alkanolamine described above, and the like can be used. Among these, in a case where alkanolamine is used, a pH can be easily adjusted and the dispersion stability of the silver colloidal particles to be formed can be further improved.

Here, if a pH exceeds 12 by adding excessive alkaline compound, hydroxide of ions, such as ferric ions, of the reducing agent that remains is easily precipitated.

Next, an aqueous liquid containing silver salt is delivered by drops into the aqueous solution obtained by dissolving the dispersant and the reducing agent that are prepared.

Silver salt is not especially limited but may be silver acetate, silver carbonate, silver oxide, silver sulfate, silver nitrite, silver chlorate, silver sulfide, silver chromate, silver nitrate, silver dichromate, for example. Among these, silver nitrate having high solubility with respect to water is preferably used.

The amount of silver salt is determined in view of a desired content of the colloidal particles and a desired reducing ratio by the reducing agent. In a case of silver nitrate, the amount is preferably about 15 pts.wt to about 70 pts.wt with respect to the aqueous solution of 100 pts.wt.

The silver salt aqueous solution is prepared by dissolving above-described silver salt in purified water. Then the silver salt aqueous solution is delivered little by little by drops into the aqueous solution in which the dispersant and the reducing agent described above are dissolved.

In this step, silver salt is reduced to silver particles by the reducing agent and the dispersant adsorbs onto surfaces of the silver particles so as to form silver colloidal particles. Thus an aqueous solution in which the silver colloidal particles are dispersed is obtained.

The resulting solution contains residues of the reducing agent and the dispersant as well as the colloidal particles, showing a high ionic concentration. In the liquid in such state, coagulation and precipitation easily occur. Therefore, washing is preferably conducted so as to remove extra ions in the aqueous solution and decrease the ionic concentration.

As a method of washing, for example, the following steps are repeated several times as: leaving the aqueous solution containing the colloidal particles at rest for a certain period, removing a supernatant solution that is produced from the aqueous solution, adding purified water to the solution and stirring the solution again, further leaving the solution at rest for a certain period, removing a newly produced supernatant solution, and the like. A method in which centrifugal separation is conducted instead of the leaving at rest, and a method in which ions are removed by ultrafiltration may be also used.

Alternatively, the following method may be used for washing. After the solution is produced, a pH of the solution is adjusted to be in an acid range that is 5 or less, and the electrical repulsion of the surfaces of the silver particles is reduced by shifting the equilibrium of the reaction expressed in Formula (1) to the right side of the formula so as to conduct the washing in a state that the metal colloidal particles are actively agglomerated. Thus salt and a medium can be removed. The metal colloidal particles that have a sulfuric compound having a low molecular weight, such as mercapto acid, on their surfaces as the dispersant form stable bonds on surfaces of metal. Therefore, if the pH of the solution is adjusted again to be in an alkaline range that is 6 or more, the metal colloidal particles that are agglomerated are easily dispersed again, being able to obtain the metal colloidal liquid exhibiting excellent dispersion stability.

After the above step, it is preferable that an alkali hydroxide metal aqueous solution be added to the aqueous solution in which the silver colloidal particles are dispersed so as to finally adjust the pH to be 6 to 11.

Since the washing is conducted after the reduction, the concentration of sodium that is an electrolyte ion may be decreased. In the solution in such state, the equilibrium of the reaction expressed in Formula (2) below shifts to the right side of the formula. In such state, the electrical repulsion of the silver colloid is decreased, so that the dispersibility of the silver particles is decreased. Therefore, the equilibrium of the reaction expressed in Formula (2) is shifted to the left side of the formula by adding an appropriate amount of alkali hydroxide, stabilizing the silver colloid.

—COO⁻Na⁺+H₂O→—COOH+Na⁺+OH⁻ (2)

The alkali hydroxide metal used here may be a compound same as the compound used when the pH is first adjusted, for example.

In the case of a pH that is less than 6, the equilibrium of the reaction expressed in Formula (2) shifts to the right side of the formula, making the colloidal particles unstable. On the other hand, if the pH exceeds 11, hydroxide salt of remaining ions such as a metal ion unfavorably precipitates with ease. Here, if the metal ion is removed in advance, the pH exceeding 11 does not affect largely.

Cations such as sodium ions are preferably added in the form of a hydroxide. This is because self protolysis of water can be used so as to be able to most effectively add the cations such as sodium ions to the aqueous solution.

Further, in the step adjusting the pH 6 to 11, alkanolamine may be used instead of the alkali hydroxide metal aqueous solution.

By adding the compound expressed by Formula (I) and other components such as alkanolamine described above to the aqueous solution obtained as above in which the silver colloidal particles are dispersed, a conductor pattern forming ink (the conductor pattern forming ink of the invention) is obtained.

The addition timing of the compound expressed by Formula (I) and other components such as alkanolamine is not especially limited. They may be added anytime after the silver colloidal particles are formed.

### Third Embodiment

Conductor Pattern

A conductor pattern according to a third embodiment of the invention will now be described.

The conductor pattern is formed such that the ink described above is applied on the ceramic formed body and then the ceramic formed body is heated so as to have a thin film shape. On the conductor pattern, the silver particles are bonded to each other. The silver particles are bonded to each other with no space therebetween at least on the surface of the conductor pattern.

Especially, the conductor pattern is formed by using the conductor pattern forming ink of the first embodiment, so that disconnections, contact between the conductor patterns which are adjacent to each other, and the like that are caused by discharge defects are prevented. Accordingly, the conductor pattern is homogenized without cracks and disconnections so as to be highly reliable.

The conductor pattern of the embodiment is formed such that the ink described above is applied on the ceramic formed body by the droplet discharge method to form a pattern (precursor), then the formed pattern is dried (the aqueous dispersion medium is removed) and sintered.

As the drying condition, the drying is preferably conducted at 40 degrees Celsius to 100 degrees Celsius, for example, more preferably 50 degrees Celsius to 70 degrees Celsius. Such condition can more effectively prevent the occurrence of cracks when the ink is dried. The sintering is conducted at 160 degrees Celsius or more for 20 minutes or more. The sintering of the precursor can be conducted together with degreasing and sintering of the ceramic formed body.

The specific resistance of the conductor pattern is preferably less than 20 μΩcm, more preferably 15 μΩcm or less. The specific resistance here is a specific resistance after the ink is applied, heated at 160 degrees Celsius, and dried. If the specific resistance becomes 20 μΩcm or more, it becomes hard to use the pattern for a purpose requiring conductivity, that is, to apply the pattern as an electrode and the like formed on a circuit substrate.

In forming the conductor pattern of the third embodiment, a conductor pattern having a large film thickness can be formed by repeating the following steps: applying the ink by the droplet discharge method, pre-heating the ink so as to evaporate the dispersion medium such as water, and applying the ink on a film after undergoing the pre-heating.

The compound expressed by Formula (I) described above and the silver colloidal particles remain in the ink after the dispersion medium such as water is evaporated, so that the pattern does not flow even in a state that the pattern formed is not completely dried. Therefore, after the ink is once applied, dried, and left for long periods of time, the ink can be applied again.

In addition, the organic binder (especially, the polyglycerol compound) described above is chemically and physically stable. Therefore, even if the ink is left for long periods of time after applied and dried, the ink does not change in quality, whereby the ink can be applied again. Thus a homogeneous pattern can be formed. Therefore, the conductor pattern is not formed as a multilayer structure, so that the increase of the specific resistance, which is caused by the increase of the specific resistance between layers, of the whole of the conductor pattern does not occur.

Through the above-described steps, the conductor pattern of the embodiment can be formed thicker than a conductor pattern formed from a related art ink. Concretely, a pattern having the thickness of 5 μm or more can be formed. The conductor pattern of the embodiment is formed from the ink described above. Therefore, even if the pattern is formed to have the thickness of 5 μm or more, the pattern hardly has cracks and has low specific resistance. The upper limit of the thickness is not especially limited. However, if the thickness is too large, the specific resistance may disadvantageously increase due to the difficulty of removing the aqueous dispersion medium, the organic binder, and the like. Therefore, the thickness is preferably about 100 μm or less.

Further, the conductor pattern of the embodiment has favorable adhesiveness with respect to the substrate described above.

The conductor pattern described above is applicable to a high frequency module of mobile communication equipment such as mobile phones and personal digital assistants (PDAs); interposers; micro electro mechanical systems (MEMS); acceleration sensors; surface acoustic wave elements; dissimilar electrodes such as antennas and comb-teeth electrodes; and electronic components of various types of measurement apparatuses, for example.

### Fourth Embodiment

Wiring Substrate and Method for Manufacturing Wiring Substrate

A wiring substrate (ceramic circuit substrate) including a conductor pattern formed from the conductor pattern forming ink of the first embodiment and an example of a method for manufacturing the wiring substrate will now be described.

A wiring substrate according to a fourth embodiment of the invention is used as an electronic component for various electronic apparatuses. The wiring substrate has a circuit pattern including various wiring lines and electrodes, a laminated ceramic capacitor, a laminated inductor, an LC filter, a composite high frequency component, and the like that are formed thereon.

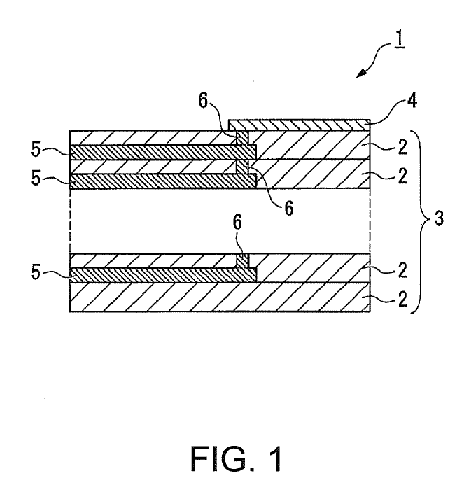

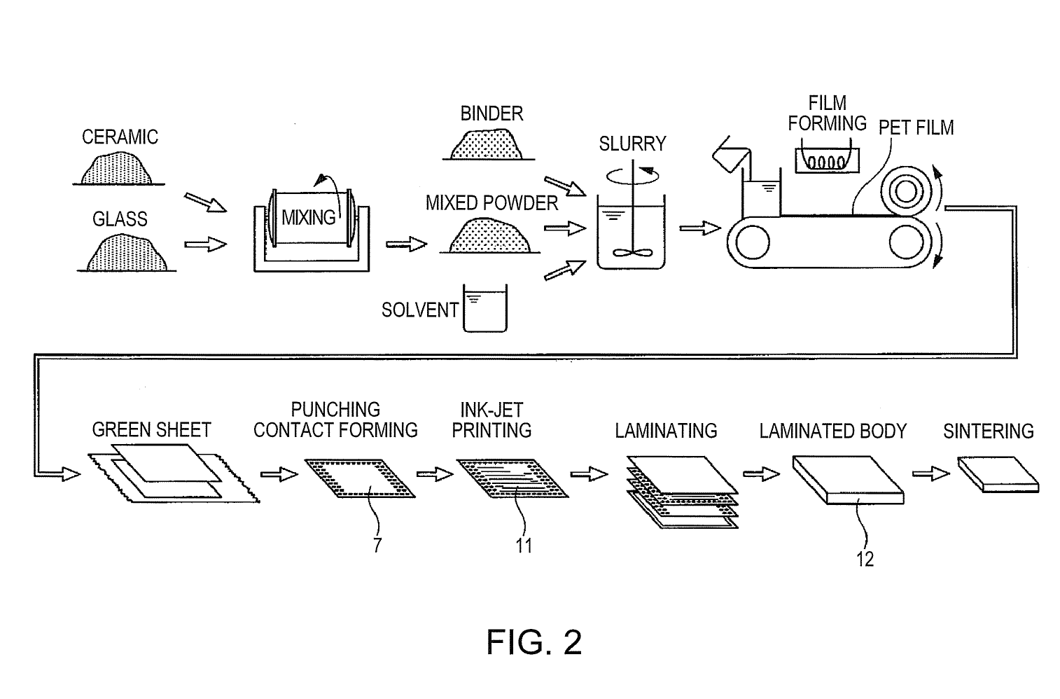

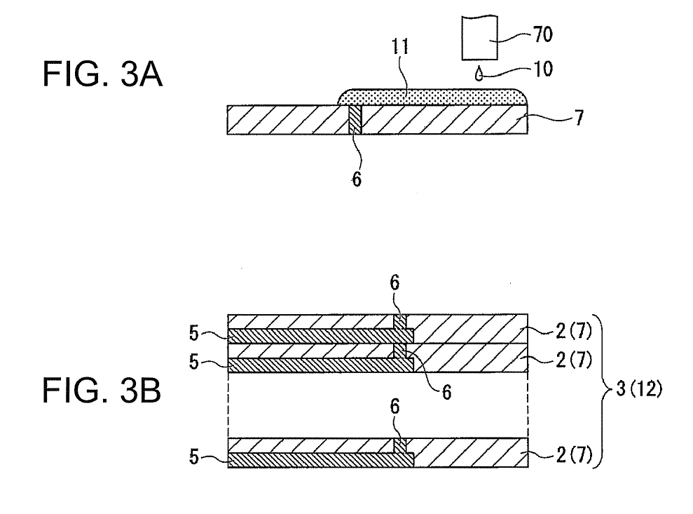

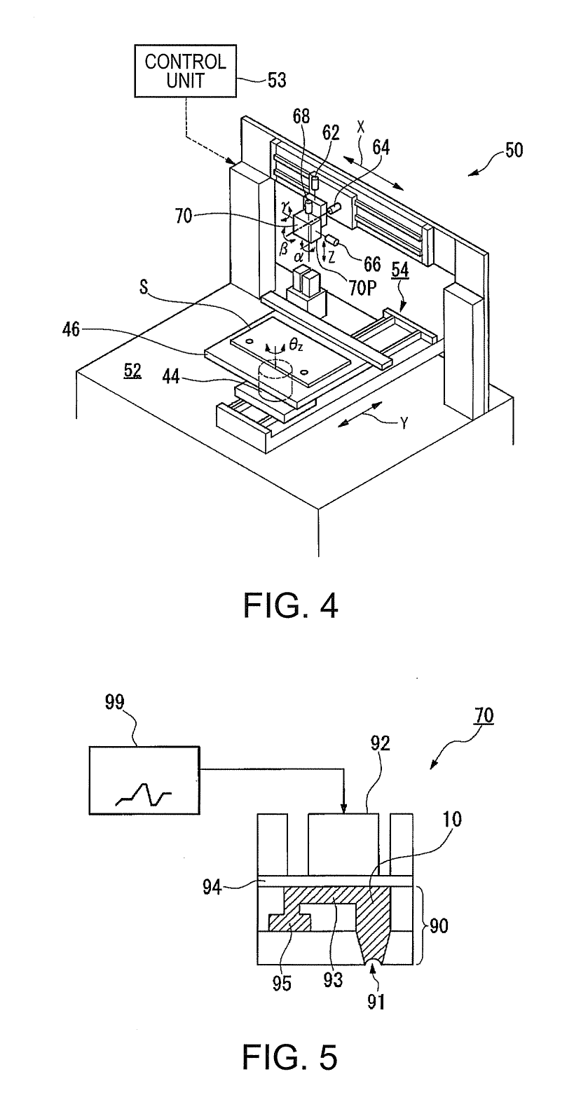

FIG. 1 is a longitudinal sectional view illustrating the wiring substrate (ceramic circuit substrate) according to the fourth embodiment. FIG. 2 is an explanatory diagram schematically showing manufacturing steps in the method for manufacturing the wiring substrate (ceramic circuit substrate) shown in FIG. 1. FIGS. 3A and 3B are explanatory diagrams showing the manufacturing steps of the wiring substrate (ceramic circuit substrate) shown in FIG. 1. FIG. 4 is a perspective view schematically showing a configuration of an ink-jet device (droplet discharge device). FIG. 5 is a schematic diagram for explaining an outline configuration of an ink-jet head (droplet discharge head).

Referring to FIG. 1, this ceramic circuit substrate (wiring substrate) 1 includes a laminated substrate 3 and a circuit 4. The laminated substrate 3 is composed of a number of ceramic substrates 2 (e.g. from about 10 to 20 sheets) that are laminated. The circuit 4 includes a fine wiring line and the like and is formed on an outermost layer of the laminated substrate 3, i.e., one of surfaces of the laminated substrate 3.

The laminated substrate 3 is provided with circuits (conductor patterns) 5 formed from the conductor pattern forming ink (hereinafter, simply referred to as “ink”) between the ceramic circuit substrates 2 that are laminated.

Further, contacts (via holes) 6 are formed between the circuits 5 so as to couple the circuits 5 with each other. In this configuration, the contact 6 electrically couples the circuits 5 disposed one above the other. Further, likewise the circuit 5, the circuit 4 is formed from the conductor pattern forming ink of the first embodiment.

Now, a method for manufacturing the ceramic circuit substrate 1 will be described with reference to FIG. 2 schematically showing the manufacturing steps. First, a ceramic powder made of alumina (Al₂O₃), titanium oxide (TiO₂), or the like having an average particle diameter of about from 1 μm to 2 μm and a glass powder made of borosilicate glass or the like having an average particle diameter of from about 1 μm to 2 μm are prepared as raw powders and mixed in an arbitrary mixing ratio such as a weight ratio of 1:1, for example.

Then, a binder (binding agent), a plasticizer, an organic solvent (dispersant), and the like are arbitrarily added to the obtained mixed powder and followed by mixing and agitating, providing a slurry. Here, polyvinyl butyral is preferably used as the binder. Polyvinyl butyral is insoluble in water, but soluble in an oil-based organic solvent or easy to swell.

The obtained slurry is formed in a sheet-like shape on a PET film by employing a doctor blade, a reverse coater, or the like so as to be a sheet having a thickness of several micrometers to several hundred micrometers based on manufacturing conditions of a product. Thereafter, the sheet is rolled up.

Subsequently, the sheet is cut as application of the product, and further, trimmed in a predetermined size. In the fourth embodiment, the sheet is cut out in a square shape having a side length of 200 mm, for example.

Then, a through hole is formed at a predetermined position by using CO₂ laser, YAG laser, a mechanical puncher, or the like as necessary.

The through hole is filled with a thick-film conductive paste having metal particles dispersed therein, forming a portion to be the contact 6. Further, the thick-film conductive paste is applied by screen printing so as to form a terminal portion (not shown) at a predetermined position. Resulting from forming the contact and the terminal portion as above, a ceramic green sheet (ceramic formed body) 7 is obtained. As the thick-film conductive paste, the conductor pattern forming ink of the first embodiment can be used.

Then, a precursor of the circuit 5, which is the conductive pattern of the invention, is continuously formed from the contact 6 on one of the surfaces of the ceramic green sheet 7 obtained as above. That is, as shown in FIG. 3A, a conductor pattern forming ink (hereinafter, also simply referred to as “ink”) 10 as described above is applied on the ceramic green sheet 7 by a droplet discharge (ink-jet) method, thus forming a precursor 11 that becomes the circuit 5.

In the fourth embodiment, the conductor pattern forming ink is discharged with an ink-jet device (droplet discharge device) 50 shown in FIG. 4 and an ink-jet head (droplet discharge head) 70 shown in FIG. 5, for example. The ink-jet device 50 and the ink-jet head 70 will now be described below.

FIG. 4 is a perspective view showing the ink-jet device 50. In FIG. 4, an X direction is the right-and-left direction of a base 52, a Y direction is the back and forth direction of the same, and a Z direction is the up and down direction of the same.

The ink-jet device 50 includes the ink-jet head (hereinafter, simply referred to as a “head”) 70 and a table 46 on which a substrate S (the ceramic green sheet 7 in the fourth embodiment) is to be placed. An operation of the ink-jet device 50 is controlled by a control unit 53.

The table 46 on which the substrate S is to be placed is permitted to move and to be positioned in the Y direction by a first moving unit 54, and is permitted to oscillate and to be positioned in a θz direction by a motor 44.

On the other hand, the head 70 is permitted to move and to be positioned in the X direction by a second moving unit (not shown), and is permitted to move and to be positioned in the Z direction by a linear motor 62. Further, the head 70 is permitted to be oscillated and to be positioned in α, β, and γ directions, respectively by motors 64, 66, and 68. The ink-jet device 50 configured as above is designed so as to precisely control a relative position and posture between an ink discharging surface 70P of the head 70 and the substrate S on the table 46.

Further, on the back surface of the table 46, a rubber heater (not shown) is provided. The rubber heater heats the entire upper surface of the ceramic green sheet 7 placed on the table 46 up to a predetermined temperature.

After the ink 10 lands on the ceramic green sheet 7, at least part of an aqueous dispersion medium in the ink 10 evaporates from the surface. Here, since the ceramic green sheet 7 is heated, the evaporation of the aqueous dispersion medium is accelerated. Then, the ink 10 landed on the ceramic green sheet 7 increases its viscosity from the outer edge of the surface as it is dried. That is, the concentration of solid matter (particles) in the outer circumference reaches a saturated concentration faster than that in the center portion, so that the ink 10 increases its viscosity from the outer edge of the surface. The ink 10 having the viscosity increased at the outer edge stops itself from spreading along the surface direction of the ceramic green sheet 7, thereby facilitating a control of a landed diameter, and further facilitating a control of a line width.

A heating temperature here employs the same condition for drying described above.

The head 70 discharges the ink 10 from a nozzle (discharge portion) 91 by an ink-jet method (droplet discharge method) as shown in FIG. 5.

As the droplet discharge method, various known techniques can be applied. Examples of the droplet discharge method include a piezoelectric method in which an ink is discharged by using a piezo element as a piezoelectric element, and a method in which an ink is discharged by a bubble that is generated by heating the ink. Among these methods, the piezoelectric method has an advantage such as that the composition of an ink is not affected because no heat is applied to the ink. Thus, the piezoelectric method mentioned above is adopted for the head 70 shown in FIG. 5.

A main body 90 of the head 70 includes a reservoir 95 and a plurality of ink chambers 93 that are divaricated from the reservoir 95. The reservoir 95 serves as a flow channel to supply the ink 10 into each of the ink chambers 93.

On the bottom surface of the main body 90, a nozzle plate (not shown) constituting an ink discharge surface is attached. In the nozzle plate, a plurality of nozzles 91 for discharging the ink 10 are opened corresponding to the ink chambers 93. Then, an ink flow channel is formed toward the corresponding nozzle 91 from each of the ink chambers 93. On the other hand, a vibrating plate 94 is attached to the top surface of the main body 90. The vibrating plate 94 constitutes a wall surface of each of the ink chambers 93. At the outer side of the vibrating plate 94, a piezo element 92 is disposed correspondingly to each of the ink chambers 93. The piezo element 92 is formed such that a piezoelectric material such as quartz crystal is sandwiched between a pair of electrodes (not shown). The pair of electrodes is coupled to a drive circuit 99.

When an electrical signal is inputted from the drive circuit 99 to the piezo element 92, the piezo element 92 is deformed and expanded or deformed and contracted. When the piezo element 92 is deformed and contracted, the pressure in the ink chamber 93 is lowered, allowing the ink 10 to flow into the ink chamber 93 from the reservoir 95. On the other hand, when the piezo element 92 is deformed and expanded, the pressure in the ink chamber 93 is increased, allowing the ink 10 to be discharged from the nozzle 91. Here, the deformation amount of the piezo element 92 can be controlled by changing a voltage to be applied. Further, the deformation speed of the piezo element 92 can be controlled by changing a frequency of a voltage to be applied. That is, discharging conditions of the ink 10 can be controlled by controlling the voltage applied to the piezo element 92.

Therefore, the ink-jet device 50 provided with the head 70 as above can precisely discharge and dispose the ink 10 in a desired amount at a desired position on the ceramic green sheet 7. Further, since the conductor pattern forming ink of the first embodiment is used as the ink 10, the ink 10 is prevented from being dried in the head 70, thus preventing metal particles from being separated out. Therefore, the precursor 11 is precisely and easily formed as shown in FIG. 3A.

After the precursor 11 is formed as above, the ceramic green sheet 7 will be formed in a required number, for example, about 10 to 20 sheets, through the same steps.

Subsequently, PET films are removed from these ceramic green sheets and the ceramic green sheets are layered as shown in FIG. 2, providing a laminated body 12. Here, the ceramic green sheets 7 to be laminated are arranged so that the precursors 11 are coupled to one another as necessary through the contract 6 between the ceramic green sheets 7 disposed one above the other. Thereafter, the ceramic green sheets 7 are bonded to each other with a pressure while being heated at a temperature more than or equal to a glass-transition temperature of a binder included in the ceramic green sheets 7. The laminated body 12 is thus obtained.

Then, the laminated body 12 formed as above is subjected to heat treatment with a belt furnace or the like, for example. The ceramic green sheets 7 are thus sintered to be the ceramic substrates 2 (the wiring substrate of the fourth embodiment) as shown in FIG. 3B. Further, silver colloidal particles in the precursor 11 are sintered to be the circuit (conductor pattern) 5 including wiring patterns and electrode patterns. The laminated body 12 is thus processed through the heat treatment as above so as to be the laminated substrate 3 shown in FIG. 1.

Here, the temperature to heat the laminated body 12 is preferably more than or equal to a softening temperature of glass included in the ceramic green sheet 7, more specifically, from 600 to 900 degrees Celsius inclusive. Further, as the heating conditions, the temperature is increased or decreased at an appropriate speed, and further, maintained for an appropriate period of time depending on the highest heating temperature, that is, the temperature from 600 to 900 degrees Celsius as above.

Thus the heating temperature is increased up to the softening temperature of the glass, that is, the temperature in the range described above, being able to soften a glass component in the ceramic substrate 2 that is obtained. Therefore, by cooling down the laminated body 12 to a room temperature so as to harden the glass component, the ceramic substrates 2 and the circuits (conductor patterns) 5 that constitute the laminated substrate 3 are further firmly bonded to each other.

Further, by heating the laminated body 12 in the temperature range above, such the ceramic substrate 2 is obtained that is a low temperature co-fired ceramic (LTCC) formed by being sintered at 900 degrees Celsius or less.

Here, metal particles included in the ink 10 deposited on the ceramic green sheet 7 are fused and continuously coupled to each other by the heat treatment, thereby exhibiting electrical conductivity.

Through the heat treatment as above, the circuit 5 is formed to be directly coupled with the contact 6 in the ceramic substrate 2, and electrically conducted. Here, if the circuit 5 is simply placed on the ceramic substrate 2, the circuit 5 cannot securely have mechanical connection strength with the ceramic substrate 2, and therefore may be damaged by impact or the like. However, in the fourth embodiment, the glass included in the ceramic green sheet 7 is softened once and then hardened as described above, firmly bonding the circuit 5 to the ceramic substrate 2. Therefore, the circuit 5 that is formed can also have mechanically high strength.

Through the heat treatment as above, the circuit 4 is concurrently formed with the circuit 5, thus providing the ceramic circuit substrate 1.

In the method for manufacturing the ceramic circuit substrate 1 as above, in particular in the manufacturing step of the ceramic substrates 2 constituting the laminated substrate 3, the ink 10 (the conductor pattern forming ink of the invention) described above is deposited on the ceramic green sheet 7, so that the conductor pattern forming ink 10 is favorably deposited on the ceramic green sheet 7 in a desired pattern. Therefore, the conductor pattern (circuit) 5 with high accuracy is formed.

While the preferred embodiments of the invention have been described, they are not intended to limit the invention.

For example, in the embodiments, a case where a colloidal liquid is used as a dispersion liquid obtained by dispersing metal particles in a solvent has been described, however, the dispersion liquid is not necessarily the colloidal liquid.

Further, in the embodiments described above, a case where the conductor pattern forming ink includes silver particles dispersed therein has been described, however, the conductor pattern forming ink may include metal particles other than silver particles. Examples of metals included in the metal particles include silver, copper, palladium, platinum, and gold or their alloys. These may be used singly or in combination of two or more. When the metal particles are made of an alloy, the alloy may include metals other than the above as long as a metal among the metals described above is used as a main constituent of the alloy. Further, an alloy made of the metals described above mixed with each other at an arbitrary ratio may be used. Furthermore, a liquid including mixed particles (e.g. silver particles, copper particles, and palladium particles are included at an arbitrary ratio) dispersed therein may be used. These metals have small resistivity and are stable because they are not oxidized by heat treatment. Therefore, using these metals make it possible to form a stable conductor pattern having low resistivity.

In the above embodiments, a case where the conductor pattern forming ink is applied to the ceramic formed body, for example, and sintered so as to form a ceramic substrate and a conductor pattern has been described, however, the conductor pattern forming ink may be applied to a substrate other than the ceramic formed body. As the substrate used for forming the conductor pattern is not particularly limited. Examples of materials for the substrate includes a ceramic sintered body, an alumina sintered body, polyimide resin, phenol resin, glass epoxy resin, glass, and the like. Alternatively, the conductor pattern forming ink may be directly applied on a ceramic substrate.

### WORKING EXAMPLES

Hereinafter, the invention will be described in further detail by using working examples, but the invention is not limited to the examples.

[1] Preparation of Conductor Pattern Forming Ink

Each of conductor pattern forming inks of Examples and Comparative Examples was produced as below.

### Examples 1 to 25

In 50 mL of water that was alkalified by adding 3 mL of a 10N—NaOH aqueous solution, 17 g of trisodium citrate dihydrate and 0.36 g of tannic acid were dissolved. Then, 3 mL of a 3.87 mol/L silver nitrate aqueous solution was added to the obtained solution and the solution was agitated for 2 hours, thus providing a silver colloidal liquid.

The silver colloidal liquid having been obtained was desalinated until its electrical conductivity became 30 μS/cm or less through dialysis. After the dialysis, bulky metal colloidal particles were removed by centrifugal separation under conditions of 3000 rpm for 10 minutes.

To the silver colloidal liquid, urea, triethanolamine, sugar alcohol, polyglycerol, Surfynol 104PG50 (produced by Air Products and Chemicals, Inc.) and Olfine EXP4036 (produced by Nissin Chemical Industry Co., Ltd) that serve as acetylene glycon based compounds were added as shown in Table 1, and an ion-exchanged water for adjusting the concentration was added so as to adjust the liquid. Thus the conductor pattern forming ink was produced.

Contents of constituent materials of the conductor pattern forming ink are shown in Table 1.

### Comparative Example 1

A conductor pattern forming ink was produced in the same manner as in Example 1 except for that no urea was added and compounding amounts of other components were changed as shown in Table 1.

### Comparative Example 2

A conductor pattern forming ink was produced in the same manner as in Example 1 except for that thiourea was added instead of urea and compounding amounts of other components were changed as shown in Table 1.

### Comparative Example 3

A conductor pattern forming ink was produced in the same manner as in Example 1 except for that no urea and no alkanolamine were added and the compounding amount of other component was changed as shown in Table 1.

### Comparative Example 4

A conductor pattern forming ink was produced in the same manner as in Example 1 except for that no alkanolamine was added and compounding amounts of other components were changed as shown in Table 1.

Here, in Table 1, triethanolamine is indicated as TEA, monoethanolamine is indicated as MEA, diethanolamine is indicated as DEA, xylitol is indicated as KI, and sorbitol is indicated as SB.

TABLE 1

| | Silver | | | | | | | | Acetylene glycol | | | | |
|---|---|---|---|---|---|---|---|---|---|---|---|---|---|
| | colloidal | | | | | | Polyglycerol | | based compound | | | | |
| | particles | Urea | Alkanolamine | | Sugar alcohol | | | Weight-average | Surfynol | Olfine | Others | | Water |
| | Content | Content | | Content | | Content | Content | molecular | 104PG50 | EXP4036 | | Content | Content |
| | [wt %] | [wt %] | Type | [wt % ] | Type | [wt %] | [wt %] | weight | [wt %] | [wt %] | Type | [wt %] | [wt %] |
| Example 1 | 40 | 10 | TEA | 5 | KI | 6 | 9 | approx. 500 | 0.02 | 0.006 | — | — | 29.974 |
| Example 2 | 40 | 15 | TEA | 5 | KI | 3 | 9 | approx. 500 | 0.02 | 0.006 | — | — | 27.974 |
| Example 3 | 40 | 20 | TEA | 5 | KI | 1.5 | 9 | approx. 500 | 0.02 | 0.006 | — | — | 24.474 |
| Example 4 | 40 | 8 | TEA | 5 | KI | 6 | 9 | approx. 500 | 0.02 | 0.006 | — | — | 31.974 |
| Example 5 | 40 | 5 | TEA | 5 | KI | 6 | 9 | approx. 500 | 0.02 | 0.006 | — | — | 34.974 |
| Example 6 | 40 | 3 | TEA | 5 | KI | 6 | 9 | approx. 500 | 0.02 | 0.006 | — | — | 36.974 |
| Example 7 | 40 | 10 | — | — | — | — | — | — | 0.02 | 0.006 | — | — | 49.974 |
| Example 8 | 40 | 10 | TEA | 3 | KI | 6 | 9 | approx. 500 | 0.02 | 0.006 | — | — | 31.974 |
| Example 9 | 40 | 10 | TEA | 1 | KI | 6 | 9 | approx. 500 | 0.02 | 0.006 | — | — | 33.974 |
| Example 10 | 40 | 10 | TEA | 5 | SB | 6 | 9 | approx. 500 | 0.02 | 0.006 | — | — | 29.974 |
| Example 11 | 40 | 10 | TEA | 5 | KI | 2 | 9 | approx. 600 | 0.02 | 0.006 | thiourea | 2 | 31.974 |
| Example 12 | 40 | 10 | TEA | 5 | — | — | — | — | 0.02 | 0.006 | — | — | 44.974 |
| Example 13 | 40 | 5 | TEA | 10 | KI | 6 | 9 | approx. 500 | 0.02 | 0.006 | — | — | 29.974 |
| Example 14 | 40 | 5 | TEA | 15 | KI | 3 | 9 | approx. 500 | 0.02 | 0.006 | — | — | 27.974 |
| Example 15 | 40 | 5 | TEA | 20 | KI | 1.5 | 9 | approx. 500 | 0.02 | 0.006 | — | — | 24.474 |
| Example 16 | 40 | 5 | TEA | 8 | KI | 6 | 9 | approx. 500 | 0.02 | 0.006 | — | — | 31.974 |
| Example 17 | 40 | 5 | TEA | 5 | KI | 6 | 9 | approx. 500 | 0.02 | 0.006 | — | — | 34.974 |
| Example 18 | 40 | 5 | TEA | 3 | KI | 6 | 9 | approx. 500 | 0.02 | 0.006 | — | — | 36.974 |
| Example 19 | 40 | — | TEA | 10 | — | — | — | — | 0.02 | 0.006 | — | — | 49.974 |
| Example 20 | 40 | 3 | TEA | 10 | KI | 6 | 9 | approx. 500 | 0.02 | 0.006 | — | — | 31.974 |
| Example 21 | 40 | 1 | TEA | 10 | KI | 6 | 9 | approx. 500 | 0.02 | 0.006 | — | — | 33.974 |
| Example 22 | 40 | 5 | TEA | 10 | SB | 6 | 9 | approx. 500 | 0.02 | 0.006 | — | — | 29.974 |
| Example 23 | 40 | 5 | MEA | 10 | KI | 6 | 9 | approx. 600 | 0.02 | 0.006 | — | — | 29.974 |
| Example 24 | 40 | 5 | DEA | 10 | KI | 6 | 9 | approx. 600 | 0.02 | 0.006 | — | — | 29.974 |
| Example 25 | 40 | 5 | TEA | 10 | — | — | — | — | 0.02 | 0.006 | — | — | 44.974 |
| *Comp. Eg. 1 | 40 | — | — | — | KI | 10 | 9 | approx. 500 | 0.02 | 0.006 | — | — | 40.974 |
| Comp. Eg. 2 | 40 | — | — | — | — | — | — | — | 0.02 | 0.006 | thiourea | 10 | 49.974 |
| Comp. Eg. 3 | 40 | — | — | — | KI | 10 | 9 | approx. 500 | 0.02 | 0.006 | — | — | 40.974 |
| Comp. Eg. 4 | 40 | 1 | — | — | — | — | — | — | 0.02 | 0.006 | — | — | 58.974 |

*Comp. Eg. = Comparative Example

[2] Producing Ceramic Green Sheet

First, a ceramic green sheet (ceramic formed body) was prepared as follows.

A ceramic powder made of alumina (Al₂O₃), titanium oxide (TiO₂), or the like having an average particle diameter of about from 1 μm to 2 μm and a glass powder made of borosilicate glass or the like having an average particle diameter of from about 1 μm to 2 μm were mixed at a weight ratio of 1:1. Then, polyvinyl butyral serving as a binder (binding agent), and dibutylphthalate serving as a plasticizer were added to the mixture, and then the resulting mixture was mixed and agitated, providing a slurry. The slurry was formed in a sheet-like shape on a PET film by a doctor blade method as a ceramic green sheet, and the sheet was cut into a square having a side length of 200 mm to be used.

[3] Evaluation of Storage Stability

Right after being produced, each of the conductor pattern forming inks obtained in Examples and Comparative Examples was dropped one each on a glass substrate and left under an atmosphere at a temperature of 25 degrees Celsius and a humidity of 50%. After being left, each of the conductor pattern forming inks having been dropped was examined whether keeping a liquid state or not by inserting a glass rod into the ink. The number of days until the ink was not able to keep a liquid state after the ink was left was evaluated as a liquid state remaining period based on criteria at 4 levels.

A: Liquid state remaining period is 30 days or more.
B: Liquid state remaining period is 7 days or more and less than 30 days.
C: Liquid state remaining period is 3 days or more and less than 7 days.
D: Liquid state remaining period is less than 3 days.

[4] Evaluation of Droplet Discharge Stability

Right after being produced, each of the conductor pattern forming inks obtained in Examples and Comparative Examples was supplied to an ink-jet device such as the one shown in FIGS. 4 and 5. First, drawing with the ink-jet device including the conductor pattern forming ink as above was conducted, and it was confirmed that the ink was stably discharged. Then, the ink-jet device was left in a waiting state in which the ink-jet head was out of a drawing position in a Class 100 clean room environment at room temperature of 25 degrees Celsius and at a relative humidity of 50% for 1 week. Next, the ink-jet device was turned on and allowed to draw a solid pattern on 20 of ceramic green sheets that were obtained as above. When the ink discharge became unstable, the ink discharge was recovered to a stable state by using a predetermined cleaning mechanism installed in the ink-jet device. Thus the above operations were conducted, and the discharge stability was evaluated based on the following evaluation criteria.

A: Ink is stably discharged without nozzle clogging during drawing (good discharge stability).
B: Cleaning operation is required two times or less to obtain stable ink discharge after an occurrence of nozzle clogging during drawing (practically usable).
C: Cleaning operation is required three times or more to obtain stable ink discharge after an occurrence of nozzle clogging during drawing (practically acceptable).
D: Nozzle clogging occurred during drawing is not recovered even by cleaning operation (unsuitable for practical use).

Further, the same evaluation was performed in a case where the same operations were carried out after the waiting state of 30 days.

[5] Production and Evaluation of Ceramic Circuit Substrate

Each of the conductor pattern forming inks obtained in Examples and Comparative Examples was supplied to an ink-jet device such as the one shown in FIGS. 4 and 5.

Then, the ceramic green sheet described above was heated to and maintained at 60 degrees Celsius. Droplets each of which was 15 ng were discharged in sequence from each discharge nozzle so as to draw 20 lines (precursor) having a line width of 40 μm, a thickness of 15 μm, and a length of 10.0 cm. A distance between the lines was set to be 5 mm. Then, the ceramic green sheet having the lines formed thereon was loaded in a drying furnace and heated under the conditions at 60 degrees Celsius for 30 minutes so as to be dried.

The ceramic green sheet having the lines formed thereon according to the above was regarded as a first ceramic green sheet. With each of the inks, 20 of the first ceramic green sheets were formed. Further, each of the sheets was examined whether it had cracks or not. The results are listed in Table 2. Table 2 shows the number of non-defective ceramic sheets having no cracks in the lines among the first ceramic green sheets.

Next, in other ceramic green sheets, through holes with a diameter of 100 μm were formed at both edges of the metal wiring lines by punching with a mechanical puncher or the like, thus forming 40 through holes in total. The through holes were filled with each of the conductor pattern forming inks obtained in Examples and Comparative Examples, thereby forming contacts (via holes). Further, patterns of a 2 mm square were formed on the contacts (via holes) by using each of the conductor pattern forming inks obtained in Examples and Comparative Examples with the droplet discharge device so as to form terminal portions.

The ceramic green sheets having the terminal portions formed thereon were regarded as second ceramic green sheets.

Then, one of the first ceramic green sheets was laminated under one of the second ceramic green sheets. Further, two ceramic green sheets that have not been processed were laminated thereto as a reinforcement layer, thereby providing a raw laminated body. Then, 20 blocks of the raw laminated body were formed for each of the inks so as to correspond to every one of 20 of the first ceramic green sheets.

Then, the raw laminated body was pressed with a pressure of 250 kg/cm² at 95 degrees Celsius for 30 seconds. Thereafter, the raw laminated body was sintered based on a sintering profile in which the raw laminated body was continuously heated at a rate of temperature rise of 66 degrees Celsius per hour for about 6 hours, at a rate of temperature rise of 10 degrees Celsius per hour for about 5 hours, and at a rate of temperature rise of 85 degrees Celsius per hour for about 4 hours, and after the elevated temperature process, was maintained at a highest temperature of 890 degrees Celsius for 30 minutes. A ceramic circuit substrate was thus obtained.

After being cooled down, each ceramic circuit substrate was subjected to a check on conductivity by placing a tester between terminal portions formed on 20 of the conductor patterns. A ceramic circuit substrate having 100% electrical conductivity was regarded as a non-defective substrate. Here, the electrical conductivity was obtained by dividing the number of conductor patterns having electrical conductivity in each of the ceramic circuit substrates by the number of conductor patterns (20 patterns) having been formed.

The results are shown in Table 2.

TABLE 2

| | | | | Number of | |
|---|---|---|---|---|---|
| | | | | non-defectives | Number of |
| | | | | after drawing | non-defectives |
| | Storage | Droplet discharge stability | | and drying | after sintering |
| | stability | 1-week period | 30-day period | [piece] | [piece] |
| Example 1 | A | A | A | 20 | 20 |
| Example 2 | A | A | A | 20 | 20 |
| Example 3 | A | A | A | 20 | 20 |
| Example 4 | A | B | B | 17 | 14 |
| Example 5 | A | B | B | 16 | 12 |
| Example 6 | A | B | C | 15 | 12 |
| Example 7 | A | B | B | 18 | 11 |
| Example 8 | A | A | A | 20 | 20 |
| Example 9 | A | B | A | 20 | 18 |
| Example 10 | A | A | A | 20 | 20 |
| Example 11 | A | A | A | 20 | 20 |
| Example 12 | A | A | B | 18 | 15 |
| Example 13 | A | A | A | 20 | 20 |
| Example 14 | A | A | A | 20 | 20 |
| Example 15 | A | A | A | 20 | 20 |
| Example 16 | A | B | B | 18 | 15 |
| Example 17 | A | B | B | 16 | 12 |
| Example 18 | B | B | C | 15 | 13 |
| Example 19 | A | B | B | 18 | 11 |
| Example 20 | A | A | A | 20 | 20 |
| Example 21 | A | B | A | 20 | 18 |
| Example 22 | A | A | A | 20 | 20 |
| Example 23 | B | C | C | 16 | 12 |
| Example 24 | B | B | B | 17 | 14 |
| Example 25 | A | A | B | 18 | 14 |
| Comparative | D | C | D | 10 | 5 |
| Example 1 | | | | | |
| Comparative | D | D | D | 10 | 2 |
| Example 2 | | | | | |
| Comparative | D | D | D | 8 | 2 |
| Example 3 | | | | | |
| Comparative | C | C | C | 14 | 10 |
| Example 4 | | | | | |

As shown in Table 2, the conductor pattern forming ink of the invention had excellent discharge stability. The conductor pattern and the wiring substrate formed by using the conductor pattern forming ink of the invention exhibited excellent conductivity and thus had high reliability. In contrast, results of Comparative Examples were unsatisfactory.

Further, when the content of the silver colloidal particles in the inks was changed to 20 wt % and 30 wt %, the same results as above were obtained.

The entire disclosure of Japanese Patent Application Nos: 2008-154709 and 2008-154710, filed June 12, are expressly incorporated by reference hererin.

What is claimed is:

1. A conductor pattern forming ink for forming a conductor pattern on a substrate by a droplet discharge method, comprising:
metal particles;
an aqueous dispersion medium in which the metal particles are dispersed; and
at least one of a compound expressed by Formula (I) below and alkanolamine, 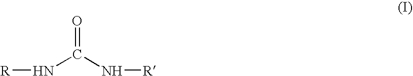
wherein R and R′ are respectively one of H and an alkyl group.

2. The conductor pattern forming ink according to claim 1, wherein a content of one of the compound expressed by Formula (I) and alkanolamine is 5 wt % to 25 wt %.

3. The conductor pattern forming ink according to claim 1, wherein alkanolamine is tertiary amine.

4. The conductor pattern forming ink according to claim 3, wherein tertiary amine is triethanolamine.

5. The conductor pattern forming ink according to claim 1, further comprising: sugar alcohol.

6. The conductor pattern forming ink according to claim 5, wherein a content of sugar alcohol is 3 wt % to 20 wt %.

7. The conductor pattern forming ink according to claim 1, wherein the substrate is formed by degreasing and sintering a ceramic formed body made of a material containing ceramic particles and a binder so as to have a sheet like shape, and the conductor pattern forming ink is applied to the ceramic formed body by the droplet discharge method.

8. The conductor pattern forming ink according to claim 1, wherein the conductor pattern forming ink is a colloidal liquid obtained by dispersing metal colloidal particles composed of the metal particles and a dispersant covering surfaces of the metal particles in the aqueous dispersion medium.

9. The conductor pattern forming ink according to claim 8, wherein the dispersant includes one of mercapto acid and salt of mercapto acid having in total two or more of at least one COOH group and at least one SH group.

10. The conductor pattern forming ink according to claim 8, wherein the colloidal liquid has a pH of 6 to 12.

11. A conductor pattern formed from the conductor pattern forming ink according to claim 1.

12. A wiring substrate provided with the conductor pattern according to claim 11.
